(19) United States
(12) Patent Application Publication
(10) Pub. No.: US 2016/0254299 A1
(43) Pub. Date: Sep. 1, 2016

(54) SOLID-STATE IMAGING DEVICE, IMAGING DEVICE, SOLID-STATE IMAGING DEVICE MANUFACTURING METHOD

(71) Applicant: OLYMPUS CORPORATION, Tokyo (JP)

(72) Inventor: Yuichi Gomi, Tokyo (JP)

(73) Assignee: OLYMPUS CORPORATION, Tokyo (JP)

(21) Appl. No.: 15/149,955

(22) Filed: May 9, 2016

Related U.S. Application Data
(63) Continuation of application No. PCT/JP2014/082696, filed on Dec. 10, 2014.

(30) Foreign Application Priority Data
Dec. 10, 2013 (JP) 2013-255423

(51) Int. Cl. H01L 27/146; H04N 5/378

(52) U.S. Cl. CPC H01L 27/1464; H01L 27/14634; H01L 27/14636; H01L 27/1469; H04N 5/378

(57) ABSTRACT

A solid-state imaging device includes a plurality of substrates provided to be overlapped and a connection structure. Each of the substrates includes a semiconductor layer in which a photoelectric conversion unit configured to convert incident light to a signal is formed, and an interconnection layer in which an interconnection configured to transmit the signal is formed and which overlaps the semiconductor layer. The semiconductor layer of a first substrate and the interconnection layer of a second substrate in two adjacent substrates among the plurality of substrates are disposed to face each other. The connection structure electrically connects the interconnection layer of the first substrate and the interconnection layer of the second substrate, and passes through only the semiconductor layer of the first substrate out of the semiconductor layer of the first substrate and the interconnection layer of the second substrate.

This application is a continuation application based on a PCT International Application No. PCT/JP2014/082696, filed on Dec. 10, 2014, whose priority is claimed on Japanese Patent Application No. 2013-255423, filed on Dec. 10, 2013, the contents of the PCT International Application and the Japanese Patent Application are incorporated herein by reference.

### BACKGROUND OF THE INVENTION

1. Field of the Invention

The present invention relates to a solid-state imaging device including a plurality of substrates, and an imaging device including the solid-state imaging device. In addition, the invention relates to a method of manufacturing a solid-state imaging device including a plurality of substrates.

2. Description of Related Art

A solid-state imaging device including a plurality of substrates is disclosed (for example, refer to Japanese Unexamined Patent Application, First Publication No. 2013-70030). For example, the solid-state imaging device has an imaging function and an auto-focusing (AF) function. In addition, the imaging device has an imaging function with visible light and an imaging function with infrared light. As described above, the solid-state imaging device can be configured to have multiple functions.

FIG. 13 shows a configuration example of the solid-state imaging device including the plurality of substrates. In FIG. 13, a cross-section of the solid-state imaging device is shown. The solid-state imaging device shown in FIG. 13 includes a plurality of overlapping substrates (a first substrate 70, a second substrate 72, and a third substrate 74), a support substrate 80, and passivation films 710, 730, and 750. The first substrate 70, the second substrate 72, and the third substrate 74 are back side illumination type solid-state imaging elements.

The first substrate 70 includes a semiconductor layer 700 and an interconnection layer 705. The semiconductor layer 700 includes a photoelectric conversion unit (PD) 701 that converts incident light to a signal. The interconnection layer 705 includes an interconnection 706 that transmits a signal generated in the photoelectric conversion unit 701, and a via 707 that connects interconnections 706 in different layers. In FIG. 13, a plurality of interconnections 706 exist, but a symbol of one interconnection 706 is shown as a representative. In addition, in FIG. 13, a plurality of vias 707 exist, but a symbol of one via 707 is shown as a representative. In the interconnection layer 705, a portion other than the interconnection 706 and the via 707 is constituted by, for example, an interlayer insulating film.

The second substrate 72 includes a semiconductor layer 720 and an interconnection layer 725. The semiconductor layer 720 includes a photoelectric conversion unit 721. The interconnection layer 725 includes an interconnection 726 and a via 727. In FIG. 13, a plurality of the interconnections 726 exist, but a symbol of one interconnection 726 is shown as a representative. In addition, in FIG. 13, a plurality of the vias 727 exist, but a symbol of one via 727 is shown as a representative. In the interconnection layer 725, a portion other than the interconnection 726 and the via 727 is constituted by, for example, an interlayer insulating film.

The third substrate 74 includes a semiconductor layer 740 and an interconnection layer 745. The semiconductor layer 740 includes a photoelectric conversion unit 741. The interconnection layer 745 includes an interconnection 746 and a via 747. In FIG. 13, a plurality of the interconnections 746 exist, but a symbol of one interconnection 746 is shown as a representative. In addition, in FIG. 13, a plurality of the vias 747 exist, but a symbol of one via 747 is shown as a representative. In the interconnection layer 745, a portion other than the interconnection 746 and the via 747 is constituted by, for example, an interlayer insulating film.

The passivation film 710 is formed between the support substrate 80 and the first substrate 70. The passivation film 730 is formed between the first substrate 70 and the second substrate 72. The passivation film 750 is formed between the second substrate 72 and the third substrate 74.

Electrodes 90, 91, 92, and 93 are formed on a surface of the semiconductor layer 740. The electrode 90 is connected to through-electrodes 900, 901, and 902 which pass through one or more sheets of substrates. The through-electrode 900 passes through the first substrate 70, the second substrate 72, and the third substrate 74. The through-electrode 900 is connected to a connection electrode 910 that is formed in the passivation film 710. The connection electrode 910 is connected to the interconnection 706 through the via 707. The through-electrode 901 passes through the second substrate 72 and the third substrate 74. The through-electrode 901 is connected to a connection electrode 911 that is formed in the passivation film 730. The connection electrode 911 is connected to the interconnection 726 through the via 727. The through-electrode 902 passes through the third substrate 74. The through-electrode 902 is connected to a connection electrode 912 that is formed in the passivation film 750. The connection electrode 912 is connected to the interconnection 746 through the via 747.

The electrode 91 is connected to a through-electrode 903 that passes through the third substrate 74. The through-electrode 903 is connected to a connection electrode 913 that is formed in the passivation film 750. The connection electrode 913 is connected to the interconnection 746 through the via 747. The electrode 92 is connected to a through-electrode 904 that passes through the second substrate 72 and the third substrate 74. The through-electrode 904 is connected to a connection electrode 914 that is formed in the passivation film 730. The connection electrode 914 is connected to the interconnection 726 through the via 727. The electrode 93 is connected to a through-electrode 905 that passes through the first substrate 70, the second substrate 72, and the third substrate 74. The through-electrode 905 is connected to a connection electrode 915 that is formed in the passivation film 710. The connection electrode 915 is connected to the interconnection 706 through the via 707.

For example, the electrode 90 is used for a power supply, a ground (GND), or a clock which is common in the respective substrates. For example, the electrodes 91, 92, and 93 are used for an individual signal in the respective substrates. For example, the individual signal in the respective substrates is a signal that is output from the photoelectric conversion units 701, 721, and 741, a clock configured to drive a circuit that is disposed at respective substrates, or a control signal that is supplied to the circuit that is disposed at the respective substrates. In a case where signals from the photoelectric conversion units 701, 721, and 741 are output to the outer side at a velocity different for each substrate, and the like, a clock different for each substrate may be supplied.

### SUMMARY OF THE INVENTION

According to a first aspect of the invention, a solid-state imaging device includes a plurality of substrates provided to be overlapped and a connection structure. Each of the substrates includes a semiconductor layer in which a photoelectric conversion unit configured to convert incident light to a signal is formed, and an interconnection layer in which an interconnection configured to transmit the signal is formed and which overlaps the semiconductor layer. The semiconductor layer of a first substrate and the interconnection layer of a second substrate in two adjacent substrates among the plurality of substrates are disposed to face each other. The connection structure is formed on a surface which faces the semiconductor layer of the first substrate, of the interconnection layer of the second substrate to electrically connect the interconnection layer of the first substrate and the interconnection layer of the second substrate, and passes through only the semiconductor layer of the first substrate out of the semiconductor layer of the first substrate and the interconnection layer of the second substrate.

According to a second aspect of the invention, the solid-state imaging device according to the first aspect may further include a resin layer that is formed between the semiconductor layer of the first substrate and the interconnection layer of the second substrate.

According to a third aspect of the invention, in the solid-state imaging device according to the second aspect, the periphery of a portion which passes through the semiconductor layer of the connection structure may be covered with a resin.

According to a fourth aspect of the invention, the solid-state imaging device according to the first aspect may further include a support substrate that overlaps a substrate which is disposed on an outermost side among the plurality of substrates. The support substrate may include a processing circuit that processes the signal that is generated in the photoelectric conversion unit formed in any one of the plurality of substrates.

According to a fifth aspect of the invention, the solid-state imaging device according to the first aspect may further include a support substrate that overlaps a substrate which is disposed on an outermost side among the plurality of substrates. The support substrate may include a drive circuit that drives a pixel including the photoelectric conversion unit formed in any one of the plurality of substrates.

According to a sixth aspect of the invention, in the solid-state imaging device according to the first aspect, a substrate that is disposed on an outermost side among the plurality of substrates, the substrate, in which the semiconductor layer is disposed on an outer side in comparison to the interconnection layer, may include an electrode that is electrically connected to the interconnection layer of the substrate and is exposed to an outer side.

According to a seventh aspect of the invention, the solid-state imaging device according to the first aspect may further include a support substrate that overlaps a substrate which is disposed on an outermost side among the plurality of substrates. The support substrate may include an electrode that is electrically connected to the interconnection layer of the substrate which overlaps the support substrate among the plurality of substrates, and is exposed to an outer side.

According to an eighth aspect of the invention, an imaging device is provided, including the solid-state imaging device according to the first aspect.

According to a ninth aspect of the invention, a method of manufacturing a solid-state imaging device is provided. The method includes: etching a part of a semiconductor layer of a first substrate including the semiconductor layer in which a photoelectric conversion unit configured to convert incident light to a signal is formed, and an interconnection layer in which an interconnection configured to transmit the signal is formed and which overlaps the semiconductor layer, to expose the interconnection layer of the first substrate; forming a connection structure which is electrically connected to the interconnection layer of a second substrate including the semiconductor layer and the interconnection layer on a surface of the interconnection layer of the second substrate; and electrically connecting the connection structure which is formed on the surface of the interconnection layer of the second substrate to the interconnection layer of the first substrate which is exposed by the etching of the semiconductor layer of the first substrate in a state in which the semiconductor layer of the first substrate and the interconnection layer of the second substrate face each other.

### BRIEF DESCRIPTION OF THE DRAWINGS

FIG. 1 is a cross-sectional view showing a configuration example of a solid-state imaging device according to a first embodiment of the invention;

FIG. 2A is a cross-sectional view showing a sequence example of manufacturing the solid-state imaging device according to the first embodiment of the invention;

FIG. 2B is a cross-sectional view showing a sequence example of manufacturing the solid-state imaging device according to the first embodiment of the invention;

FIG. 3A is a cross-sectional view showing a sequence example of manufacturing the solid-state imaging device according to the first embodiment of the invention;

FIG. 3B is a cross-sectional view showing a sequence example of manufacturing the solid-state imaging device according to the first embodiment of the invention;

FIG. 4A is a cross-sectional view showing a sequence example of manufacturing the solid-state imaging device according to the first embodiment of the invention;

FIG. 4B is a cross-sectional view showing a sequence example of manufacturing the solid-state imaging device according to the first embodiment of the invention;

FIG. 5A is a cross-sectional view showing a sequence example of manufacturing the solid-state imaging device according to the first embodiment of the invention;

FIG. 5B is a cross-sectional view showing a sequence example of manufacturing the solid-state imaging device according to the first embodiment of the invention;

FIG. 6A is a cross-sectional view showing a sequence example of manufacturing the solid-state imaging device according to the first embodiment of the invention;

FIG. 6B is a cross-sectional view showing a sequence example of manufacturing the solid-state imaging device according to the first embodiment of the invention;

FIG. 7A is a cross-sectional view showing a sequence example of manufacturing the solid-state imaging device according to the first embodiment of the invention;

FIG. 7B is a cross-sectional view showing a sequence example of manufacturing the solid-state imaging device according to the first embodiment of the invention;

FIG. 8A is a cross-sectional view showing a sequence example of manufacturing the solid-state imaging device according to the first embodiment of the invention;

FIG. 8B is a cross-sectional view showing a sequence example of manufacturing the solid-state imaging device according to the first embodiment of the invention;

FIG. 9 is a cross-sectional view showing a configuration example of a solid-state imaging device according to a second embodiment of the invention;

FIG. 10 is a cross-sectional view showing a configuration example of a solid-state imaging device according to a third embodiment of the invention;

FIG. 11 is a cross-sectional view showing a configuration example of a solid-state imaging device according to a fourth embodiment of the invention;

FIG. 12 is a block diagram showing a configuration example of an imaging device according to a fifth embodiment of the invention; and

FIG. 13 is a cross-sectional view showing a configuration example of a solid-state imaging device in the related art.

### DETAILED DESCRIPTION OF THE INVENTION

Hereinafter, embodiments of the invention will be described with reference to the accompanying drawings.

### First Embodiment

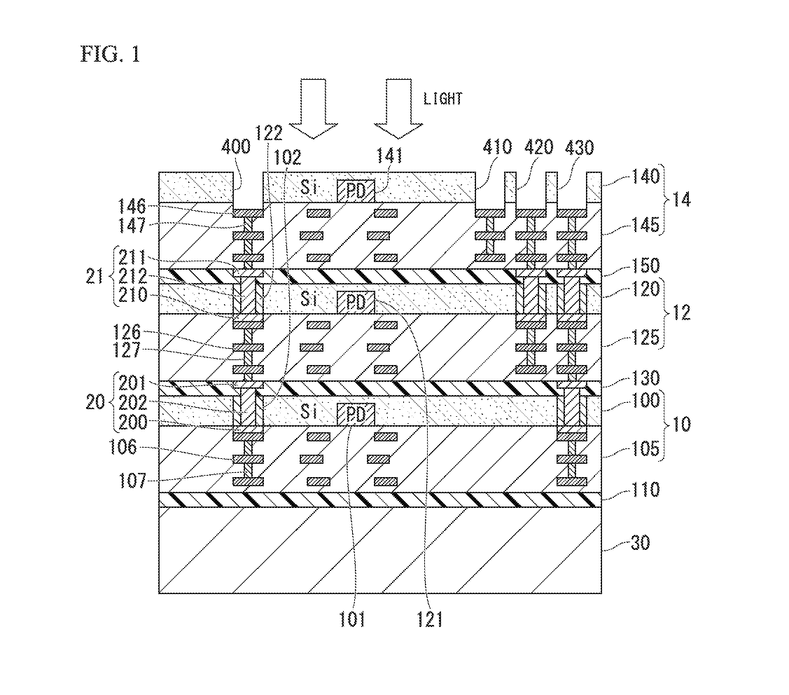

First, a first embodiment of the invention will be described. FIG. 1 shows a configuration example of a solid-state imaging device according to this embodiment. In FIG. 1, a cross-section of the solid-state imaging device is shown. The solid-state imaging device shown in FIG. 1 includes a plurality of overlapping (stacked) substrates (a first substrate 10, a second substrate 12, and a third substrate 14), connection units 20 and 21, a support substrate 30, and resin layers 110, 130, and 150. The first substrate 10, the second substrate 12, and the third substrate 14 are back side illumination type solid-state imaging elements.

The thickness and the width of portions which constitute the solid-state imaging device shown in FIG. 1 do not conform to the thickness and the width which are shown in FIG. 1. The thickness and the width of portions which constitute the solid-state imaging device shown in FIG. 1 may be set in an arbitrary manner.

The first substrate 10 includes a semiconductor layer 100 and an interconnection layer 105. The semiconductor layer 100 and the interconnection layer 105 overlap each other in a direction that is approximately perpendicular to a main surface (the widest surface among a plurality of surfaces of a substrate) of each substrate. In addition, the semiconductor layer 100 and the interconnection layer 105 come into contact with each other.

The semiconductor layer 100 includes a photoelectric conversion unit (PD) 101 that converts incident light to a signal. The semiconductor layer 100 is constituted by a material including a semiconductor such as silicon (Si). For example, the photoelectric conversion unit 101 is constituted by a semiconductor material in which a concentration of impurities is different from that of a semiconductor material that constitutes the semiconductor layer 100. The semiconductor layer 100 includes a first surface that comes into contact with the interconnection layer 105, and a second surface that is exposed to an outer side and is opposite to the first surface. Light which is incident to the second surface of the semiconductor layer 100 propagates through the inside of the semiconductor layer 100 and is incident to the photoelectric conversion unit 101.

The interconnection layer 105 includes an interconnection 106 and a via 107. The interconnection 106 transmits a signal that is generated in the photoelectric conversion unit 101, and other signals. The via 107 connects interconnections 106 in different layers. In FIG. 1, a plurality of the interconnections 106 exist, but a symbol of one interconnection 106 is shown as a representative. In addition, in FIG. 1, a plurality of the vias 107 exist, but a symbol of one via 107 is shown as a representative. The interconnection 106 is constituted by a material (for example, a metal such as aluminum (Al) and copper (Cu)) having conductivity. The interconnection layer 105 includes a first surface that comes into contact with the resin layer 110, and a second surface that is opposite to the first surface and comes into contact with the semiconductor layer 100.

The interconnection 106 is a thin film in which an interconnection pattern is formed. Only one layer of the interconnection 106 may be formed, or a plurality of layers of the interconnections 106 may be formed. In an example shown in FIG. 1, three layers of the interconnections 106 are formed. The interconnections 106 in different layers are connected to each other through the via 107. The via 107 is constituted by a material having conductivity. In the interconnection layer 105, a portion other than the interconnection 106 and the via 107 is constituted by, for example, an interlayer insulating film.

The second substrate 12 includes a semiconductor layer 120 and an interconnection layer 125. The semiconductor layer 120 and the interconnection layer 125 overlap each other in a direction that is approximately perpendicular to main surfaces of the respective substrates. In addition, the semiconductor layer 120 and the interconnection layer 125 come into contact with each other.

The semiconductor layer 120 includes a photoelectric conversion unit 121. The semiconductor layer 120 is approximately the same as the semiconductor layer 100, and thus detailed description of the semiconductor layer 120 will not be repeated.

The interconnection layer 125 includes an interconnection 126 and a via 127. In FIG. 1, a plurality of the interconnections 126 exist, but a symbol of one interconnection 126 is shown as a representative. In addition, in FIG. 1, a plurality of the vias 127 exist, but a symbol of one via 127 is shown as a representative. The interconnection layer 125 is approximately the same as the interconnection layer 105, and detailed description of the interconnection layer 125 will not be repeated.

The third substrate 14 includes a semiconductor layer 140 and an interconnection layer 145. The semiconductor layer 140 and the interconnection layer 145 overlap each other in a direction that is approximately perpendicular to main surfaces of the respective substrates. In addition, the semiconductor layer 140 and the interconnection layer 145 come into contact with each other.

The semiconductor layer 140 includes a photoelectric conversion unit 141. The semiconductor layer 140 is approximately the same as the semiconductor layer 100, and thus detailed description of the semiconductor layer 140 will not be repeated.

The interconnection layer 145 includes an interconnection 146 and a via 147. In FIG. 1, a plurality of the interconnections 146 exist, but a symbol of one interconnection 146 is shown as a representative. In addition, in FIG. 1, a plurality of the vias 147 exist, but a symbol of one via 147 is shown as a representative. The interconnection layer 145 is approximately the same as the interconnection layer 105, and thus detailed description of the interconnection layer 145 will not be repeated.

The support substrate 30 supports the plurality of substrates which are provided to the solid-state imaging device. The support substrate 30 overlaps any one of the plurality of substrates which are provided to the solid-state imaging device. In an example shown in FIG. 1, the support substrate 30 overlaps the first substrate 10. The support substrate 30 includes a first surface that is exposed to an outer side, and a second surface that is opposite to the first surface and comes into contact with the resin layer 110.

Two adjacent substrates among the plurality of substrates which are provided to the solid-state imaging device are connected to each other through each of the resin layers 110, 130, and 150. For example, the resin layers 110, 130, and 150 are constituted by an epoxy resin. Joining strength between the substrates further increases due to the resin layers 110, 130, and 150.

The resin layer 110 is formed between the support substrate 30 and the first substrate 10. The support substrate 30 and the first substrate 10 are connected to each other through the resin layer 110 in a state in which the support substrate 30 and the interconnection layer 105 of the first substrate 10 face each other. The resin layer 110 comes into contact with the second surface of the support substrate 30 and the first surface of the interconnection layer 105. The first substrate 10 is insulated from the support substrate 30 with the resin layer 110.

The resin layer 130 is formed between the first substrate 10 and the second substrate 12. The first substrate 10 and the second substrate 12 are connected to each other through the resin layer 130 in a state in which the semiconductor layer 100 of the first substrate 10 and the interconnection layer 125 of the second substrate 12 face each other. The resin layer 130 comes into contact with the second surface of the semiconductor layer 100 and a first surface of the interconnection layer 125. The second substrate 12 is insulated from the first substrate 10 with the resin layer 130.

The resin layer 150 is formed between the second substrate 12 and the third substrate 14. The second substrate 12 and the third substrate 14 are connected to each other through the resin layer 150 in a state in which the semiconductor layer 120 of the second substrate 12 and the interconnection layer 145 of the third substrate 14 face each other. The resin layer 150 comes into contact with a second surface of the semiconductor layer 120 and a first surface of the interconnection layer 145. The third substrate 14 is insulated from the second substrate 12 with the resin layer 150.

Each of the connection units 20 and 21 is disposed between two adjacent substrates, and electrically connects the two substrates. In FIG. 1, a plurality of connection units 20 exist, but a symbol of one connection unit 20 is shown as a representative. In addition, in FIG. 1, a plurality of the connection units 21 exist, but a symbol of one connection unit 21 is shown as a representative. The connection units 20 and 21 are constituted by a material (for example, a metal such as gold (Au) and copper (Cu)) having conductivity.

The connection unit 20 electrically connects the first substrate 10 and the second substrate 12. The connection unit 20 includes connection electrodes 200 and 201, and a bump 202. The connection electrode 200 is formed in the interconnection layer 105.

The connection electrode 200 is connected to the interconnection 106. An under barrier metal (UBM) such a titanium (Ti) may be formed between the connection electrode 200 and the interconnection 106. The connection electrode 201 is formed in the resin layer 130. The connection electrode 201 is connected to the interconnection 126 through the via 127. An UBM such as titanium (Ti) may be formed between the connection electrode 201 and the via 127.

The bump 202 is connected to the connection electrodes 200 and 201. The bump 202 comes into contact with the connection electrode 200 that is connected to the interconnection 106. Accordingly, the bump 202 is electrically connected to the interconnection 106. In addition, the bump 202 comes into contact with the connection electrode 201 that is electrically connected to the interconnection 126. Accordingly, the bump 202 is electrically connected to the interconnection 126.

The bump 202 passes through the semiconductor layer 100. The height of the bump 202 is greater than the thickness of the semiconductor layer 100. Accordingly, the bump 202 is formed across the semiconductor layer 100 and the resin layer 130. The bump 202 is a connection structure that electrically connects the interconnection layer 105 (interconnection 106) of the first substrate 10, and the interconnection layer 125 (interconnection 126) of the second substrate 12, and passes through only the semiconductor layer 100 of the first substrate 10 in the semiconductor layer 100 of the first substrate 10 and the interconnection layer 125 of the second substrate 12.

In the bump 202, the periphery of a portion that passes through the semiconductor layer 100 is surrounded by an insulating layer 102. The insulating layer 102 is constituted by a material (for example, silicon dioxide (SiO₂)) having insulating properties. The bump 202 is insulated from the semiconductor layer 100 with the insulating layer 102.

The connection unit 21 electrically connects the second substrate 12 and the third substrate 14. The connection unit 21 includes connection electrodes 210 and 211, and a bump 212. The connection electrode 210 is formed in the interconnection layer 125. The connection electrode 210 is connected to the interconnection 126. UBM such as titanium (Ti) may be formed between the connection electrode 210 and the interconnection 126. The connection electrode 211 is formed in the resin layer 150. The connection electrode 211 is connected to the interconnection 146 through the via 147. An UBM such as titanium (Ti) may be formed between the connection electrode 211 and the via 147.

The bump 212 is connected to the connection electrodes 210 and 211. The bump 212 comes into contact with the connection electrode 210 that is connected to the interconnection 126. Accordingly, the bump 212 is electrically connected to the interconnection 126. In addition, the bump 212 comes into contact with the connection electrode 211 that is electrically connected to the interconnection 146. Accordingly, the bump 212 is electrically connected to the interconnection 146.

The bump 212 passes through the semiconductor layer 120. The height of the bump 212 is greater than the thickness of the semiconductor layer 120. Accordingly, the bump 212 is formed across the semiconductor layer 120 and the resin layer 150. The bump 212 is a connection structure that electrically connects the interconnection layer 125 (interconnection 126) of the second substrate 12, and the interconnection layer 145 (interconnection 146) of the third substrate 14, and passes through only the semiconductor layer 120 of the second substrate 12 in the semiconductor layer 120 of the second substrate 12 and the interconnection layer 145 of the third substrate 14.

In the bump 212, the periphery of a portion that passes through the semiconductor layer 120 is surrounded by an insulating layer 122. The insulating layer 122 is constituted by a material (for example, silicon dioxide (SiO₂)) having insulating properties. The bump 212 is insulated from the semiconductor layer 120 with the insulating layer 122.

Grooves 400, 410, 420, and 430 (openings) are formed in the semiconductor layer 140 and the interconnection layer 145. At the bottom of the grooves 400, 410, 420, and 430, a part of the interconnection 146 is exposed to an outer side. The thickness of the semiconductor layer 140 is, for example, 10 μm or less, and the width of the grooves 400, 410, 420, and 430 is, for example, 50 μm to 100 μm. For example, a conductive wire from an outer side can be connected to the interconnection 146 through wire bonding. The interconnection 146, which is exposed at positions at which the grooves 400, 410, 420, and 430 are formed, is an electrode that outputs a signal from the solid-state imaging device to an outer side, or applies a signal from an outer side to the solid-state imaging device. That is, in the solid-state imaging device shown in FIG. 1, the third substrate 14 is a substrate that is disposed on an outermost side among the plurality of substrates in which the photoelectric conversion unit is formed. In the third substrate 14, the semiconductor layer 140 is disposed on an outer side in comparison to the interconnection layer 145. The third substrate 14 includes an electrode (interconnection 146) that is electrically connected to the interconnection layer 145 of the third substrate 14, and is exposed to an outer side.

A substrate which is disposed on an outermost side among the plurality of substrate is a substrate including a main surface that does not come into contact with other substrates among the plurality of substrates. In the solid-state imaging device shown in FIG. 1, the first substrate 10 and the third substrate 14 are disposed on an outermost side. In a case where the solid-state imaging device includes only two substrates in which the photoelectric conversion unit is formed, the two substrates are disposed on an outermost side. In other words, a substrate which is disposed on an outermost side among the plurality of substrates is a substrate that is disposed on an uppermost side or a lowermost side among the plurality of substrates in a case where the plurality of substrates are disposed in such a manner that at least any one main surface of the plurality of substrates is approximately parallel to the horizontal surface.

For example, an electrode at a position at which the groove 400 is formed is used for a power supply, a ground (GND), or a clock which is common in the respective substrates. For examples, electrodes at positions, at which the grooves 410, 420, and 430 are formed, are used for individual signals at respective substrates. Examples of the individual signals at the respective substrates include signals output from the photoelectric conversion units 101, 121, and 141, clocks configured to drive circuits which are disposed at the respective substrates, or control signals which are supplied to the circuits which are disposed at the respective substrates. In a case where signals from the photoelectric conversion units 101, 121, and 141 are output to an outer side at a velocity different for each substrate, and the like, a clock different for each substrate may be supplied. The electrode at a position, at which the groove 410 is formed, is used for an individual signal of the third substrate 14. The electrode at a position, at which the groove 420 is formed, is used for an individual signal of the second substrate 12. The electrode at a position, at which the groove 430 is formed, is used for an individual signal of the first substrate 10.

For example, a signal that is output from the photoelectric conversion unit 101 is transmitted to the second substrate 12 through the connection unit 20 at a position at which the groove 430 is formed. The signal which is transmitted to the second substrate 12 is transmitted to the third substrate 14 through the connection unit 21. The signal which is transmitted to the third substrate 14 is output to an outer side from the electrode at a position at which the groove 430 is formed. For example, a signal which is output from the photoelectric conversion unit 121 is transmitted to the third substrate 14 through the connection unit 21 at a position at which the groove 420 is formed. The signal which is transmitted to the third substrate 14 is output to an outer side from the electrode at a position at which the groove 420 is formed. For example, a signal which is output from the photoelectric conversion unit 141 is output to an outer side from the electrode at a position at which the groove 410 is formed.

The solid-state imaging device shown in FIG. 1 includes three substrates in which the photoelectric conversion unit is formed. However, the solid-state imaging device may include two substrates or four or more substrates in which the photoelectric conversion unit is formed. In addition, in the solid-state imaging device shown in FIG. 1, adjacent substrates are connected to each other through each of the resin layers 110, 130, and 150, but a method of connecting the adjacent substrates is not limited thereto. In addition, an electrode formed from a metal or the like which is connected to the interconnection 146 may be formed at the bottom of the grooves 400, 410, 420, and 430.

A structure that does not directly relate to structures (for example, the photoelectric conversion units 101, 121, and 141) which are necessary for the solid-state imaging device, or a structure that does not directly relates to the connection units 20 and 21 are not characteristic structures of the solid-state imaging device according to this embodiment. That is, the support substrate 30, the insulating layers 102 and 122, the resin layers 110, 130, and 150, the vias 107, 127, and 147, and the grooves 400, 410, 420, and 430 are not characteristic structures of the solid-state imaging device according to this embodiment. In addition, these structures are not structures which are necessary to obtain characteristic effects of the solid-state imaging device according to this embodiment.

In addition, the connection electrodes 200 and 201 of the connection unit 20 are auxiliary structures which connect the bump 202 to the interconnection layer 105 and the interconnection layer 125, and are not structures which are necessary to obtain the characteristic effects of the solid-state imaging device according to this embodiment. This is also true of the connection electrodes 210 and 211 of the connection unit 21.

In the above-described structure, the bump 202 passes through only the semiconductor layer 100, and the bump 212 passes through only the semiconductor layer 120. According to this, it is possible to manufacture the bumps 202 and 212 in an easier manner in comparison to case of forming a through-electrode that passes through one or more substrates. That is, it is possible to provide a solid-state imaging device that can be more easily manufactured.

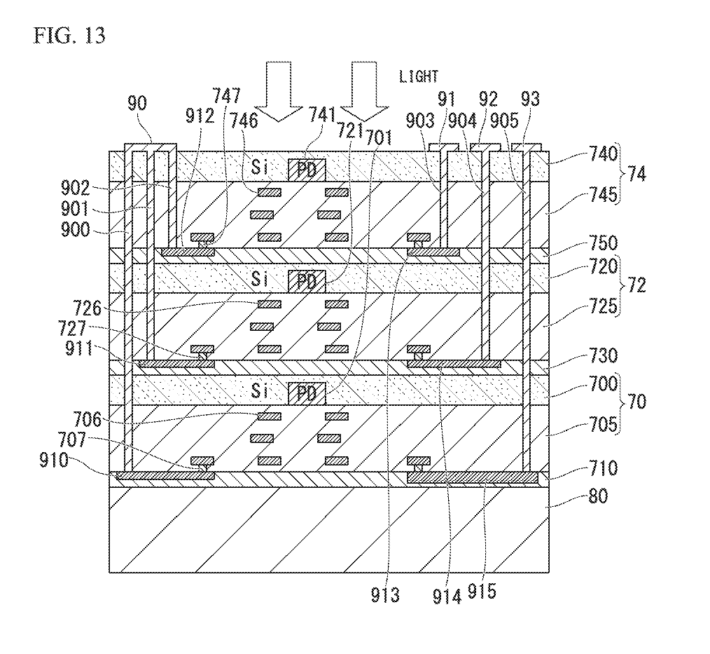

In a solid-state imaging device of the related art shown in FIG. 13, in order for through-electrodes 900, 901, and 902 which are connected to an electrode 90 to be common to one through-electrode, it is necessary to form the through-electrode so as to pass through connection electrodes 910, 911, and 912 which are formed in respective substrates. However, it is difficult to form the through-electrode so as to pass through the connection electrodes 910, 911, and 912 which are formed from a metal. Accordingly, it is necessary to provide the through-electrodes 900, 901, and 902 separately without being common. In this case, regions are necessary to separately provide the through-electrodes 900, 901, and 902. Therefore, it is difficult to realize miniaturization of the solid-state imaging device.

In the solid-state imaging device shown in FIG. 1, it not necessary to prepare a plurality of structures which correspond to respective substrates for a power supply and the like which are common to the plurality of substrates. For example, at a position at which the groove 400 is formed, power is applied to the interconnection layer 145 from an outer side, and the power is supplied to the third substrate 14. The power which is applied to the interconnection layer 145 is simultaneously applied to the interconnection layer 125 through the bump 212. According to this, the power is supplied to the second substrate 12. In addition, the power which is applied to the interconnection layer 125 is simultaneously applied to the interconnection layer 105 through the bump 202. According to this, the power is supplied to the first substrate 10. That is, a structure which is necessary for the power supply and the like which are common to the plurality of substrates can be made to be common. Accordingly, it is possible to minimize the solid-state imaging device.

As described above, in this embodiment, the bumps 202 and 212 contribute to miniaturization of the solid-state imaging device. According to this, it is possible to provide a solid-state imaging device that is miniaturized and can be more easily manufactured.

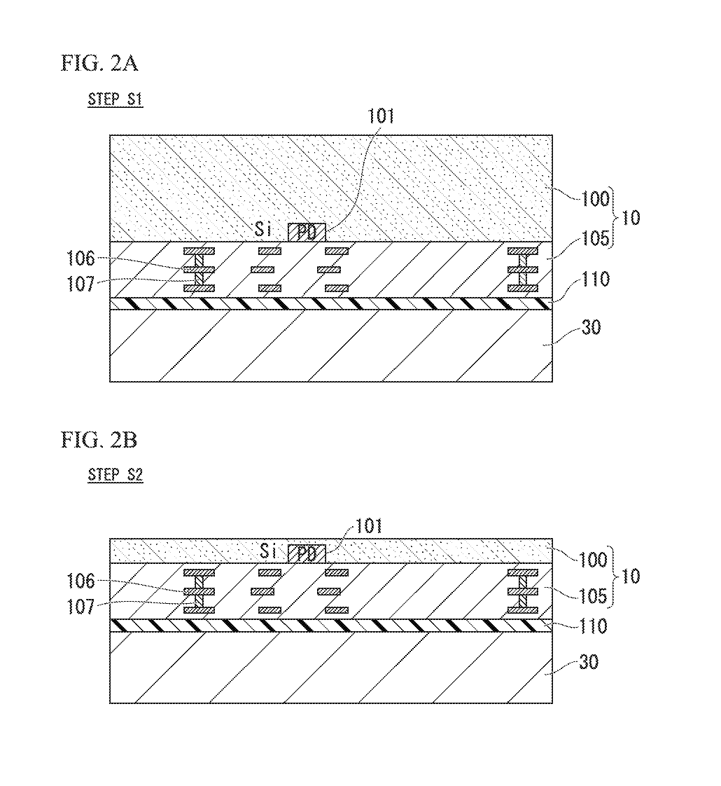

Next, description will be given of a method of manufacturing the solid-state imaging device according to this embodiment. FIG. 2A to FIG. 8B show a sequence example of manufacturing the solid-state imaging device. In FIG. 2A to FIG. 8B, a cross-section of the solid-state imaging device is shown.

(Step S0)

The first substrate 10, which includes the semiconductor layer 100 and the interconnection layer 105, is prepared. The photoelectric conversion unit 101 is formed in the semiconductor layer 100. The interconnection 106 is formed in the interconnection layer 105 and overlaps the semiconductor layer 100. In addition, a second substrate 12 which includes the semiconductor layer 120 and the interconnection layer 125 is prepared. The photoelectric conversion unit 121 is formed in the semiconductor layer 120. The interconnection 126 is formed in the interconnection layer 125 and overlaps the semiconductor layer 120.

(Step S1)

The first surface of the interconnection layer 105 is connected to the support substrate 30 through the resin layer 110. According to this, the first substrate 10 is joined to the support substrate 30 through the resin layer 110 (shown in FIG. 2A).

(Step S2)

The second surface of the semiconductor layer 100 is polished. According to this, the semiconductor layer 100 becomes thin (shown in FIG. 2B).

(Step S3)

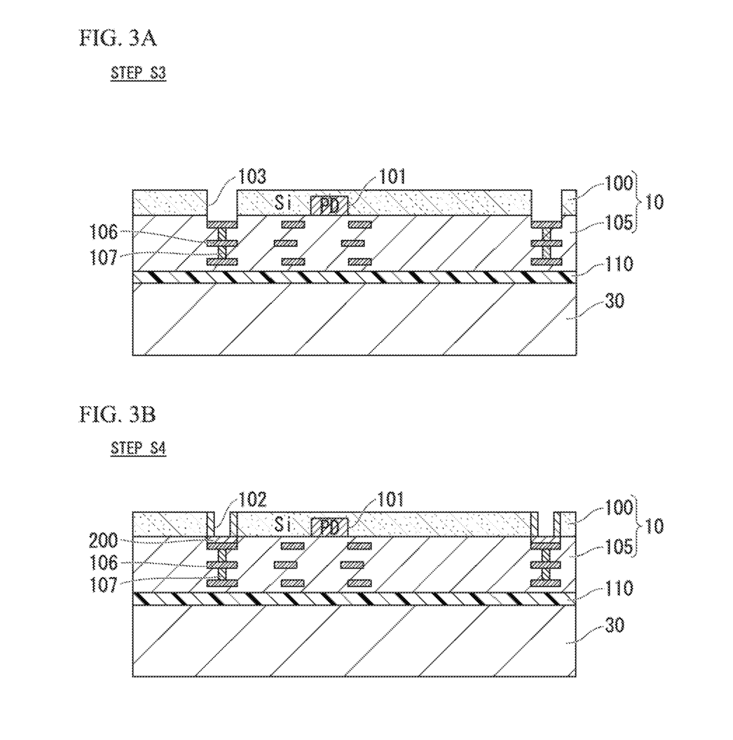

A part of the semiconductor layer 100 is etched from the second surface side to form the groove 103 in the semiconductor layer 100. At this time, etching is performed so that the groove 103 passes through the semiconductor layer 100, and the interconnection layer 105 is exposed. In an example of this embodiment, etching is performed until the interconnection 106 of the interconnection layer 105 is exposed (shown in FIG. 3A). Step S3 is a process of etching a part of the semiconductor layer 100 of the first substrate 10 including the semiconductor layer 100 and the interconnection layer 105 to expose the interconnection layer 105 of the first substrate 10. The photoelectric conversion unit 101 is formed in the semiconductor layer 100. The interconnection 106 is formed in the interconnection layer 105, and overlaps the semiconductor layer 100.

(Step S4)

The connection electrode 200 is formed on a surface of the interconnection 106 that is exposed through the etching. In addition, the insulating layer 102 is formed on a surface of the groove 103 (shown in FIG. 3B).

(Step S5)

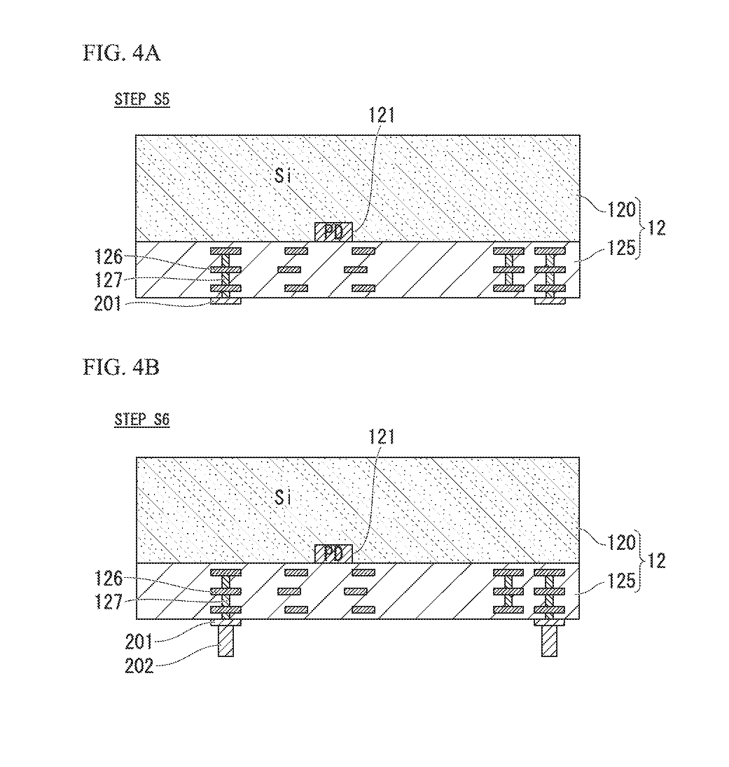

The connection electrode 201 is formed on the first surface of the interconnection layer 125 of the second substrate 12 at a position at which the via 127 is exposed. According to this, the connection electrode 201 is electrically connected to the via 127. In addition, the connection electrode 201 comes into contact with the via 127 that is connected to the interconnection 126. Accordingly the connection electrode 201 is electrically connected to the interconnection 126 (shown in FIG. 4A).

(Step S6)

The bump 202, which is connected to the connection electrode 201, is formed. The bump 202 comes into contact with the connection electrode 201 that is electrically connected to the interconnection 126. Accordingly, the bump 202 is electrically connected to the interconnection 126 (shown in FIG. 4B). It is preferable that the height of the bump 202 be greater than the thickness of the semiconductor layer 100. Step S6 is a process of forming a connection structure that is electrically connected to the interconnection layer 125 (interconnection 126) of the second substrate 12 including the semiconductor layer 120 and the interconnection layer 125.

(Step S7)

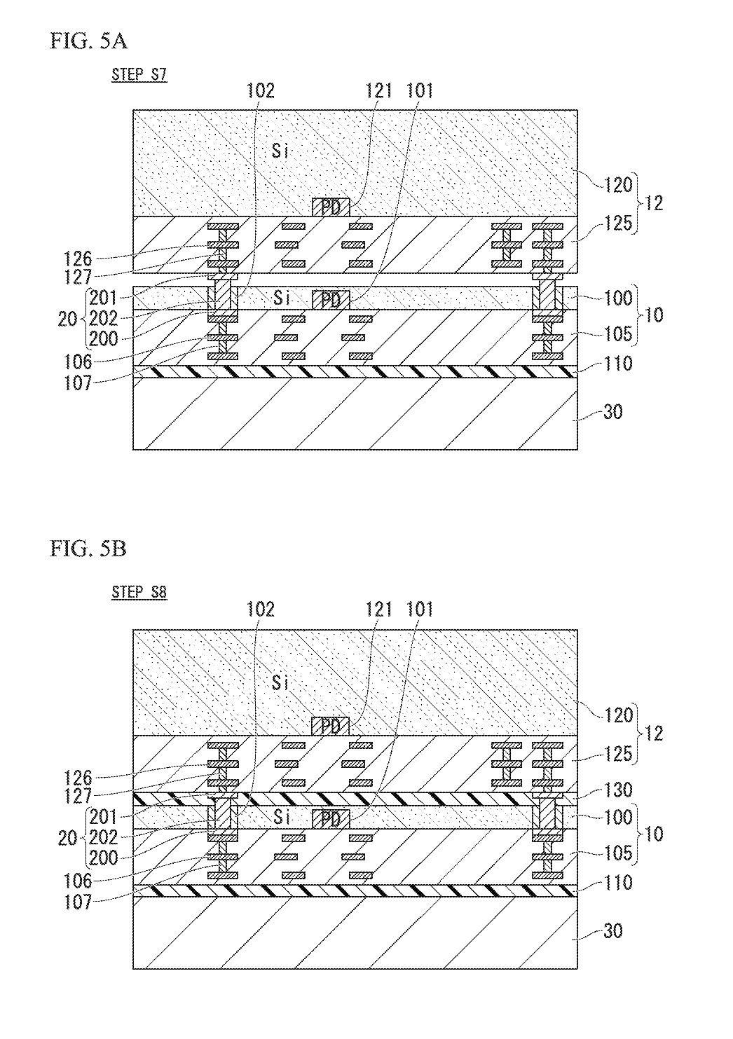

In a state in which the semiconductor layer 100 of the first substrate 10 and the interconnection layer 125 of the second substrate 12 face each other, the position of the first substrate 10 that is connected to the support substrate 30, and the position of the second substrate 12 are adjusted so that a planar position of the bump 202 and a planar position of the connection electrode 200 approximately match each other. Subsequently, the bump 202 is inserted into a groove covered with the insulating layer 102, and is connected to the connection electrode 200. According to this, the interconnection layer 105 and the interconnection layer 125 are electrically connected to each other by the connection unit 20 including the connection electrodes 200 and 201 and the bump 202, and the first substrate 10 and the second substrate 12 are joined to each other. In a state in which the first substrate 10 and the second substrate 12 are joined to each other, the bump 202 comes into contact with the connection electrode 200 that is connected to the interconnection 106. Accordingly, the bump 202 is electrically connected to the interconnection 106. In addition, in a state in which the first substrate 10 and the second substrate 12 are joined to each other, a void is present between the first substrate 10 and the second substrate 12 (shown in FIG. 5A).

Connection between the bump 202 and the connection electrode 200 is performed as follows. For example, in a state in which the semiconductor layer 100 and the interconnection layer 125 face each other, the first substrate 10 that is joined to the support substrate 30, and the second substrate 12 are interposed between compression plates. In this state, when being heated and compressed by a pressing apparatus, the bump 202 and the connection electrode 200 are electrically joined to each other. Before the bump 202 and the connection electrode 200 are joined, a surface of the first substrate 10, a surface of the second substrate 12, the connection electrodes 200 and 201, and the bump 202 may be cleaned through plasma cleaning, reverse sputtering, and the like. It is easy for the bump 202 and the connection electrode 200 to be joined due to so so-called surface activation.

Step S7 is a process of electrically connecting the bump 202 that is a connection structure to the interconnection layer 105 (interconnection 106) of the first substrate 10 which is exposed through etching with respect to the semiconductor layer 100 of the first substrate 10 in a state in which the semiconductor layer 100 of the first substrate 10 and the interconnection layer 125 of the second substrate 12 face each other.

(Step S8)

A resin fills a space between the first substrate 10 and the second substrate 12, and the resin layer 130 is formed (shown in FIG. 5B).

Formation of the resin layer 130 is performed as follows. For example, an epoxy resin which is heated and flowability thereof increases flows into a space between the first substrate 10 and the second substrate 12. Then, the epoxy resin which flows into the space is cooled down and the epoxy resin is solidified. When allowing the epoxy resin to flow into the space between the first substrate 10 and the second substrate 12, a pressure difference effect may be used.

(Step S9)

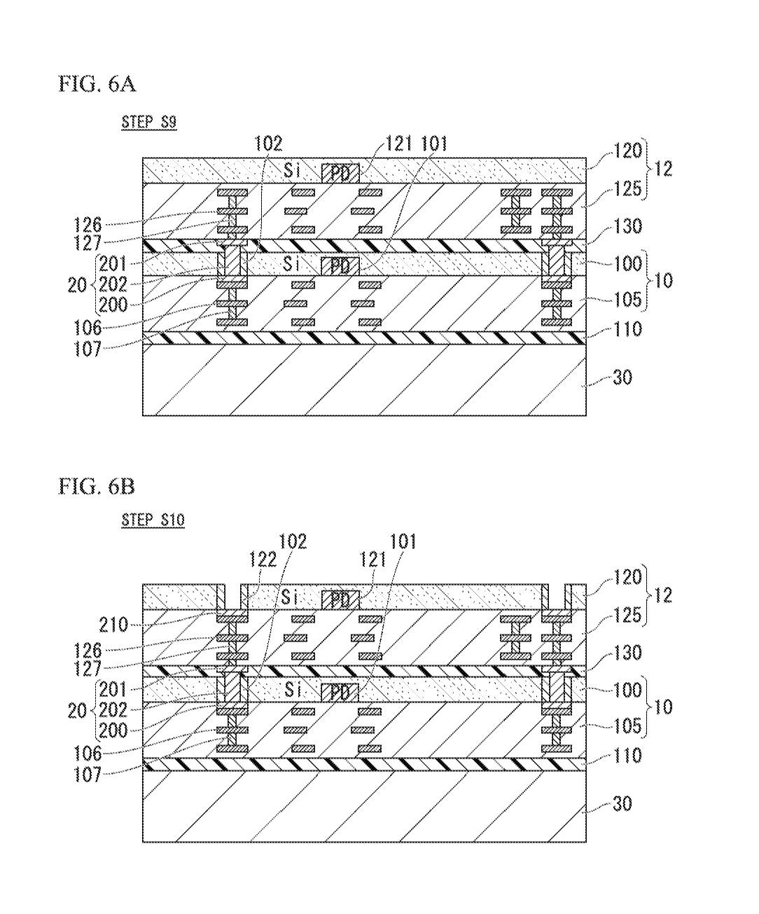

The second surface of the semiconductor layer 120 is polished. According to this, the semiconductor layer 120 becomes thin (shown in FIG. 6A).

(Step S10)

A part of the semiconductor layer 120 is etched from the second surface side to form a groove in the semiconductor layer 120. At this time, etching is performed so that the groove passes through the semiconductor layer 120, and the interconnection layer 125 is exposed. In an example of this embodiment, etching is performed until the interconnection 126 of the interconnection layer 125 is exposed. The connection electrode 210 is formed on a surface of the interconnection 126 that is exposed through etching. In addition, the insulating layer 122 is formed on a surface of the groove that is formed through etching (shown in FIG. 6B). Step S10 is a process corresponding to step S3 and step S4.

(Step S11)

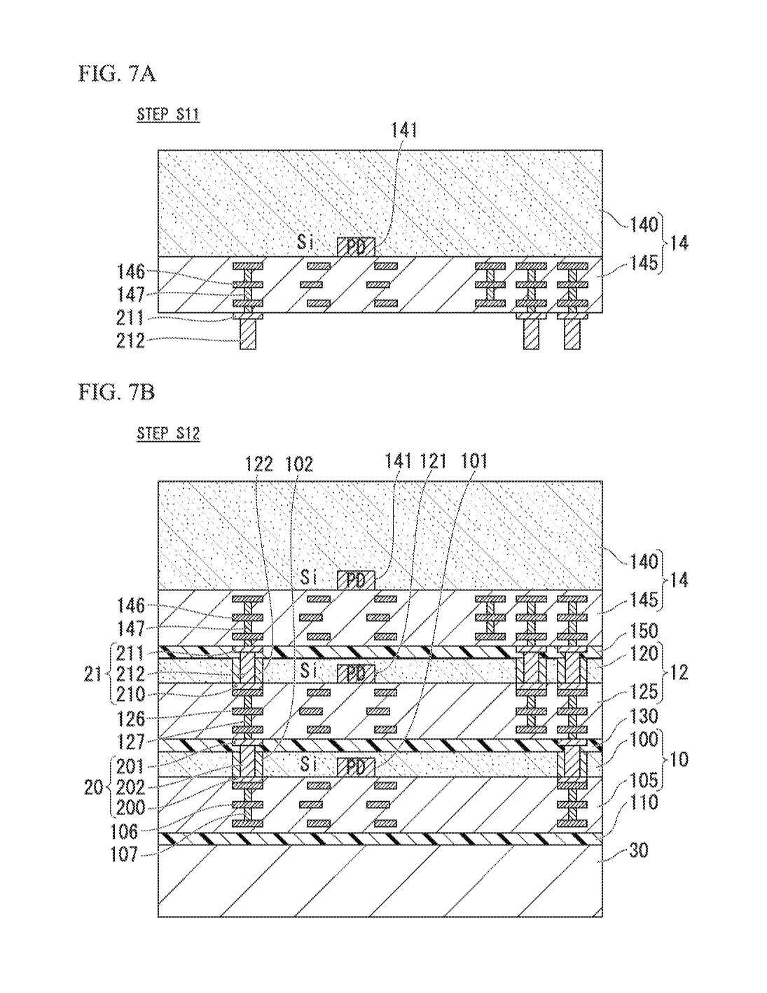

The connection electrode 211 is formed on the first surface of the interconnection layer 145 of the third substrate 14 at a position, at which the via 147 is exposed. According to this, the connection electrode 211 is electrically connected to the via 147. In addition, the connection electrode 211 comes into contact with the via 147 that is connected to the interconnection 146. Accordingly, the connection electrode 211 is electrically connected to the interconnection 146. In addition, the bump 212, which is connected to the connection electrode 211, is formed. The bump 212 comes into contact with the connection electrode 211 that is electrically connected to the interconnection 146. Accordingly, the bump 212 is electrically connected to the interconnection 146 (shown in FIG. 7A). It is preferable that the height of the bump 212 be greater than the thickness of the semiconductor layer 120. Step S11 is a process corresponding to step S5 and step S6.

(Step S12)

In a state in which the semiconductor layer 120 of the second substrate 12 and the interconnection layer 145 of the third substrate 14 face each other, the position of the second substrate 12 and the position of the third substrate 14 are adjusted so that a planar position of the bump 212 and a planar position of the connection electrode 210 approximately match each other. Subsequently, the bump 212 is inserted into a groove covered with the insulating layer 122, and is connected to the connection electrode 210. According to this, the interconnection layer 125 and the interconnection layer 145 are electrically connected to each other by the connection unit 21 including the connection electrodes 210 and 211, and the bump 212, and the second substrate 12 and the third substrate 14 are joined to each other. In a state in which the second substrate 12 and the third substrate 14 are joined to each other, the bump 212 comes into contact with the connection electrode 210 that is connected to the interconnection 126. Accordingly, the bump 212 is electrically connected to the interconnection 126. In addition, in a state in which the second substrate 12 and the third substrate 14 are joined to each other, a void is present between the second substrate 12 and the third substrate 14. In addition, a resin fills a space between the second substrate 12 and the third substrate 14 to form the resin layer 150 (shown in FIG. 7B). Step S12 is a process corresponding to step S7 and step S8.

(Step S13)

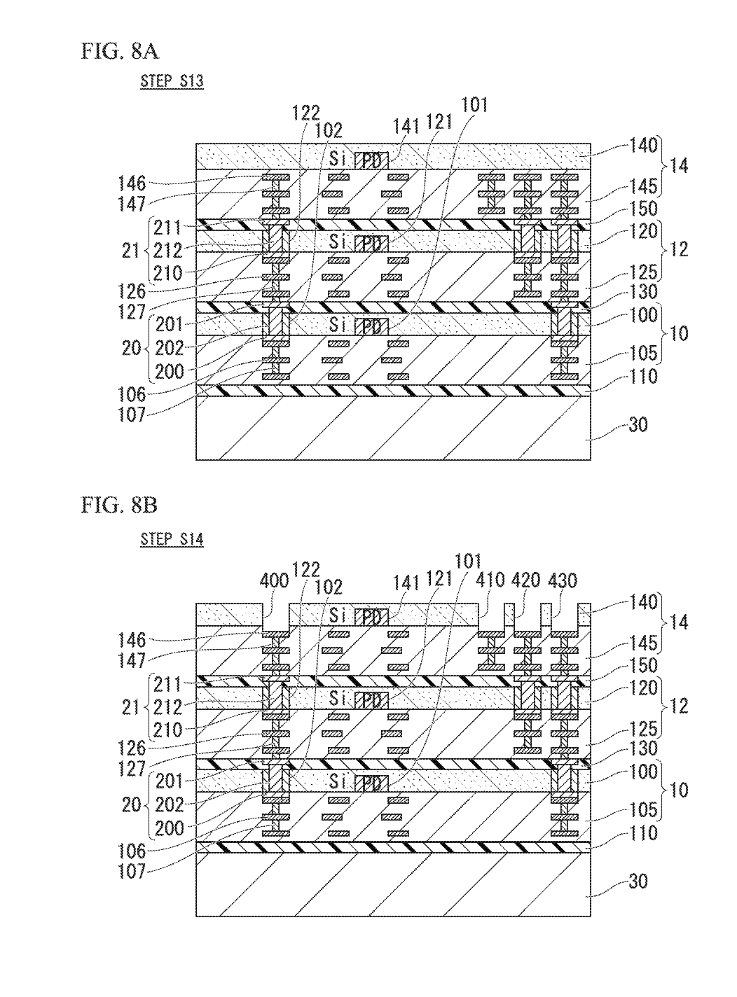

A second surface of the semiconductor layer 140 is polished. According to this, the semiconductor layer 140 becomes thin (shown in FIG. 8A).

(Step S14)

A part of the semiconductor layer 140 is etched from the second surface side to form the grooves 400, 410, 420, and 430 in the semiconductor layer 140. At this time, etching is performed so that the grooves 400, 410, 420, and 430 pass through the semiconductor layer 140 and the interconnection layer 145 is exposed. In an example of this embodiment, etching is performed until the interconnection 146 of the interconnection layer 145 is exposed. According to this, an electrode which is electrically connected to an outer side is formed (shown in FIG. 8B).

A process that does not directly relate to the process of forming the connection units 20 and 21, and a process that does not directly relate to the process of connecting the substrates by using the connection units 20 and 21 are not characteristic processes of the method of manufacturing the solid-state imaging device. That is, step S0 to step S2, step S8 and step S9, and step S13 and step S14 are not characteristic processes of the method of manufacturing the solid-state imaging device according to this embodiment. Similarly, the process of forming the insulating layer 102 in step S4, and the process of forming the resin layer 150 in step S12 are not characteristic processes of the method of manufacturing the solid-state imaging device according to this embodiment. In addition, these processes are not necessary to obtain the characteristic effects of the method of manufacturing the solid-state imaging device according to this embodiment.

In addition, the process of forming the connection electrode 200 in step S4, and the process of forming the connection electrode 201 in step S5 are auxiliary processes of connecting the bump 202 to the semiconductor layer 100 and the interconnection layer 125. Therefore, these processes are not necessary to obtain the characteristic effects of the method of manufacturing the solid-state imaging device according to this embodiment. This is also true of the process of forming the connection electrode 210 in step S10, and the process of forming the connection electrode 211 in step S11.

In the manufacturing method, the bump 202 passes through only the semiconductor layer 100, and the bump 212 passes through only the semiconductor layer 120. According to this, it is possible to more easily manufacture the bumps 202 and 212 in comparison to a case of forming a through-electrode that passes through one or more substrates. That is, it is possible to more easily manufacture the solid-state imaging device.

In addition, in the manufacturing method, it is possible to easily manufacture a common structure that is necessary for a power supply and the like which are common to a plurality of substrates. In addition, the solid-state imaging device is miniaturized due to the common structure. That is, it is possible to more easily manufacture a miniaturized solid-state imaging device.

According to this embodiment, a solid-state imaging device is provided, including a plurality of overlapping substrates (the first substrate 10, the second substrate 12, and the third substrate 14), and a connection structure (the bump 202 or the bump 212). Each of the substrates includes each of the semiconductor layers 100, 120, and 140 in which the photoelectric conversion units 101, 121, and 141 configured to convert incident light to a signal are formed, respectively, and each of the interconnection layers 105, 125, and 145 in which the interconnections 106, 126, and 146 configured to transmit the signal are formed, respectively, and which overlap the semiconductor layers 100, 120, and 140, respectively. The semiconductor layer 100 of the first substrate 10 (or the semiconductor layer 120 of the second substrate 12) and the interconnection layer 125 of the second substrate 12 (or the interconnection layer 145 of the third substrate 14) in two adjacent substrates among the plurality of substrates are disposed to face each other. The connection structure electrically connects the interconnection layer 105 of the first substrate 10 (or the interconnection layer 125 of the second substrate 12) and the interconnection layer 125 of the second substrate 12 (or the interconnection layer 145 of the third substrate 14), and passes through only the semiconductor layer 100 of the first substrate 10 (or the semiconductor layer 120 of the second substrate 12) in the semiconductor layer 100 of the first substrate 10 (or the semiconductor layer 120 of the second substrate 12) and the interconnection layer 125 of the second substrate 12 (or the interconnection layer 145 of the third substrate 14).

In addition, according to this embodiment, a method of manufacturing a solid-state imaging device is provided. The method includes a process (step S3 or Step S10) of etching a part of the semiconductor layer 100 of the first substrate 10 (or the semiconductor layer 120 of the second substrate 12) including the semiconductor layer 100 in which the photoelectric conversion unit 101 configured to convert incident light to a signal is formed, and the interconnection layer 105 in which the interconnection 106 configured to transmit the signal is formed and which overlaps the semiconductor layer 100 to expose the interconnection layer 105 of the first substrate 10 (or the interconnection layer 125 of the second substrate 12), a process (step S6 or step S11) of forming a connection structure (the bump 202 or the bump 212) which is electrically connected to the interconnection layer 125 of the second substrate 12 (or the interconnection layer 145 of the third substrate 14) including the semiconductor layer 120 and the interconnection layer 125, and a process (step S7 or step S12) of electrically connecting the connection structure (the bump 202 or the bump 212) to the interconnection layer 105 of the first substrate 10 (or the interconnection layer 125 of the second substrate 12) which is exposed through the etching of the semiconductor layer 100 of the first substrate 10 (or the semiconductor layer 120 of the second substrate 12) in a state in which the semiconductor layer 100 of the first substrate 10 (or the semiconductor layer 120 of the second substrate 12) and the interconnection layer 125 of the second substrate 12 (or the interconnection layer 145 of the third substrate 14) face each other.

In this embodiment, the interconnection layer 105 of the first substrate 10 or the interconnection layer 125 of the second substrate 12, and the interconnection layer 125 of the second substrate 12 or the interconnection layer 145 of the third substrate 14 are electrically connected to each other due to the bump 202 or the bump 212 that passes through only the semiconductor layer 100 of the first substrate 10 or the semiconductor layer 120 of the second substrate 12. Accordingly, it is possible to more easily manufacture the solid-state imaging device. In addition, it is possible to more easily manufacture a miniaturized solid-state imaging device.

### Second Embodiment

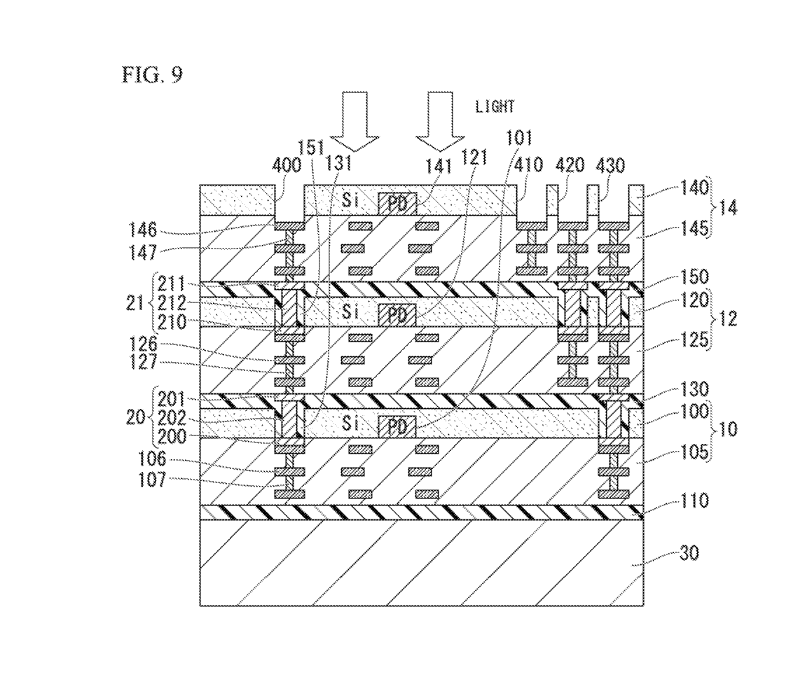

Next, description will be given of a second embodiment of the invention. FIG. 9 shows a configuration example of a solid-state imaging device according to this embodiment. In FIG. 9, a cross-section of the solid-state imaging device is shown.

In the solid-state imaging device shown in FIG. 9, the insulating layer 102 and the insulating layer 122 in the solid-state imaging device shown in FIG. 1 are changed to a resin layer 131 and a resin layer 151, respectively. That is, in the bump 202, the periphery of a portion that passes through the semiconductor layer 100 is surrounded by the resin layer 131. In addition, in the bump 212, the periphery of a portion that passes through the semiconductor layer 120 is surrounded by the resin layer 151. Structures other than the resin layers 131 and 151 are substantially the same as the structures of the solid-state imaging device shown in FIG. 1, and thus description of the structures other than the resin layers 131 and 151 will not be repeated.

A resin that constitutes the resin layer 131 is the same as the resin that constitutes the resin layer 130. In addition, a resin that constitutes the resin layer 151 is the same as the resin that constitutes the resin layer 150.

In a case of manufacturing the solid-state imaging device according to this embodiment, the processes of forming the insulating layers 102 and 122 in the first embodiment are not necessary. In this embodiment, the resin layer 131 is formed in the process of forming the resin layer 130, and the resin layer 151 is formed in the process of forming the resin layer 150.

In this embodiment, the processes of forming the insulating layers 102 and 122 in the first embodiment are not necessary. Accordingly, it is possible to manufacture the solid-state imaging device in a small number of processes.

### Third Embodiment

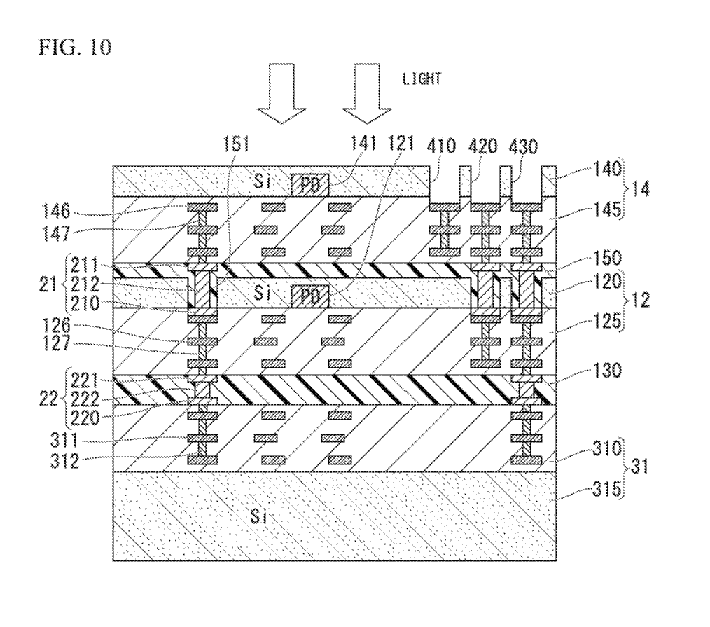

Next, description will be given of the third embodiment of the invention. FIG. 10 shows a configuration example of a solid-state imaging device according to this embodiment. In FIG. 10, a cross-section of the solid-state imaging device is shown.

In the solid-state imaging device shown in FIG. 10, the first substrate 10, the resin layer 110, and the support substrate 30 in the solid-state imaging device shown in FIG. 9 are changed to a support substrate 31, and the connection unit 20 is changed to a connection unit 22. In addition, in the solid-state imaging device shown in FIG. 10, the groove 400 in the solid-state imaging device shown in FIG. 9 is omitted. Structures other than the above-described structure are substantially the same as the structures of the solid-state imaging device shown in FIG. 9, and thus description of the structures other than the above-described structure will not be repeated. A resin layer 151 in FIG. 10 may be changed to the insulating layer 122 in FIG. 1.

The support substrate 31 overlaps the second substrate 12 that is disposed on an outermost side among the plurality of substrates in which the photoelectric conversion unit is formed. More specifically, the support substrate 31 overlaps the second substrate 12, in which the interconnection layer 125 is disposed on an outer side in comparison to the semiconductor layer 120, as a substrate that is disposed on the outermost side among the plurality of substrates in which the photoelectric conversion unit is formed. The support substrate 31 includes an interconnection layer 310 and a circuit substrate 315. The interconnection layer 310 and the circuit substrate 315 overlap each other in a direction that is perpendicular to main surfaces of the respective substrates. In addition, the interconnection layer 310 and the circuit substrate 315 come into contact with each other.

The interconnection layer 310 includes an interconnection 311 and a via 312. The interconnection 311 transmits a signal that is generated in the photoelectric conversion units 121 and 141, and the other signals. The via 312 connects interconnections 311 in different layers. In FIG. 10, a plurality of the interconnections 311 exist, but a symbol of one interconnection 311 is shown as a representative. In addition, in FIG. 10, a plurality of the vias 312 exist, but a symbol of one via 312 is shown as a representative.

The interconnection 311 is constituted by a material (for example, a metal such as aluminum (Al) and copper (Cu)) having conductivity. The interconnection layer 310 includes a first surface that comes into contact with the circuit substrate 315, and a second surface that is opposite to the first surface and comes into contact with the resin layer 130. The interconnection 311 is a thin film in which an interconnection pattern is formed. Only one layer of the interconnection 311 may be formed, or a plurality of layers of the interconnections 311 may be formed. In an example shown in FIG. 10, three layers of the interconnections 311 are formed. The interconnections 311 in different layers are connected to each other through the via 312. The via 312 is constituted by a material having conductivity. In the interconnection layer 310, a portion other than the interconnection 311 and the via 312 is constituted by, for example, an interlayer insulating film.

The circuit substrate 315 is constituted by a material such as silicon (Si) including a semiconductor. The circuit substrate 315 includes a first surface that is exposed to an outer side, and a second surface that is opposite to the first surface and comes into contact with the interconnection layer 310. For example, the circuit substrate 315 includes a processing circuit (for example, an amplification circuit) that processes a signal that is generated by the photoelectric conversion unit 121 or 141 that is formed in any one of the plurality of substrates. Alternatively, the circuit substrate 315 includes a drive circuit (for example, a reset circuit that resets the photoelectric conversion unit 121 or 141, or a transmission circuit that transmits charges accumulated in the photoelectric conversion unit 121 or 141 to a charge accumulation unit) that drives a pixel including the photoelectric conversion unit 121 or 141 that is formed in any one of the plurality of substrates. The processing circuit or the drive circuit may be formed in the interconnection layer 310.

The connection unit 22 is disposed between the support substrate 31 and the second substrate 12 which are adjacent to each other, and electrically connects the support substrate 31 and the second substrate 12. In FIG. 10, a plurality of the connection units 22 exist, but a symbol of one connection unit 22 is shown as a representative. The connection unit 22 is constituted by a material (for example, a metal such as gold (Au) and copper (Cu)) having conductivity.

The connection unit 22 includes connection electrodes 220 and 221, and a bump 222. The connection unit 22 is formed in the resin layer 130. The connection electrode 220 is connected to the interconnection 311 through the via 312. A UBM such as titanium (Ti) may be formed between the connection electrode 220 and the via 312. The connection electrode 221 is connected to the interconnection 126 through the via 127. The UBM such as titanium (Ti) may be formed between the connection electrode 221 and the via 127.

The bump 222 is connected to the connection electrodes 220 and 221. The bump 222 comes into contact with the connection electrode 220 that is connected to the interconnection 311. Accordingly, the bump 222 is electrically connected to the interconnection 311. In addition, the bump 222 comes into contact with the connection electrode 221 that is electrically connected to the interconnection 126. Accordingly, the bump 222 is electrically connected to the interconnection 126. The bump 222 connects the connection electrode 220 and the connection electrode 221 to electrically connect the interconnection layer 310 (interconnection 311) of the support substrate 31, and the interconnection layer 125 (interconnection 126) of the second substrate 12.

The structure that connects the second substrate 12 and the third substrate 14 in the solid-state imaging device shown in FIG. 10 is substantially the same as the structure that connects the first substrate 10 and the second substrate 12 in the solid-state imaging device shown in FIG. 1. According to this, it is possible to provide a solid-state imaging device that can be more easily manufactured.

In a sequence of manufacturing the solid-state imaging device shown in FIG. 10, the support substrate 31 is used instead of the first substrate 10, the resin layer 110, and the support substrate 30 in the sequence of manufacturing the solid-state imaging device shown in FIG. 1, and the connection unit 22 is formed instead of the connection unit 20. A sequence other than the above-described configuration is substantially the same as the sequence of manufacturing the solid-state imaging device shown in FIG. 1, and thus description of the sequence of manufacturing the solid-state imaging device shown in FIG. 10 will not be repeated.

Next, description will be given of a transmission route of the signal that is generated in the photoelectric conversion units 121 and 141. Hereinafter, description will be given of an example in which the signal is transmitted through the connection units 21 and 22 which are located on a left side of the photoelectric conversion units 121 and 141, and the connection units 21 and 22 which are located at a position at which the groove 430 is formed.

For example, a signal which is output from the photoelectric conversion unit 121 is transmitted to the support substrate 31 through the connection unit 22 on a left side of the photoelectric conversion units 121 and 141. The signal which is transmitted to the support substrate 31 is processed by a processing circuit that is formed in the circuit substrate 315. The signal which is processed by the processing circuit is transmitted to the second substrate 12 through the connection unit 22 at a position at which the groove 430 is formed. The signal which is transmitted to the second substrate 12 is transmitted to the third substrate 14 through the connection unit 21. The signal which is transmitted to the third substrate 14 is output to an outer side from an electrode at a position at which the groove 430 is formed.

For example, a signal which is output from the photoelectric conversion unit 141 is transmitted to the second substrate 12 through the connection unit 21 on a left side of the photoelectric conversion units 121 and 141. The signal which is transmitted to the second substrate 12 is transmitted to the support substrate 31 through the connection unit 22. The signal which is transmitted to the support substrate 31 is processed by the processing circuit that is formed in the circuit substrate 315. As described above, the signal which is processed by the processing circuit is output to an outer side from the electrode at a position at which the groove 430 is formed.

The signal that is output from the photoelectric conversion unit 121, and the signal that is output from the photoelectric conversion unit 141 may be transmitted from the second substrate 12 to the support substrate 31 through the connection units 22 different from each other. In addition, a signal may be output from the photoelectric conversion unit 121 and the photoelectric conversion unit 141 in a time-division manner, and the signal may be transmitted from the second substrate 12 to the support substrate 31 through the same connection unit 22.

Similarly, the signals which are output from the photoelectric conversion units 121 and 141 and are processed by the processing circuit may be transmitted from the support substrate 31 to the third substrate 14 through the connection units 21 and 22 different from each other. In addition, the signal that is output from the photoelectric conversion unit 121 and is processed by the processing circuit, and the signal that is output from the photoelectric conversion unit 141 and is processed by the processing circuit may be output from the processing circuit in a time-division manner, and the signal may be transmitted from the support substrate 31 to the third substrate 14 through the same connection units 21 and 22.

Hereinafter, description will be given of a transmission route of a drive signal output from the drive circuit that drives a pixel including the photoelectric conversion unit 121 or 141. Hereinafter, description will be given of an example in which the drive signal is transmitted through the connection units 21 and 22 on a left side of the photoelectric conversion units 121 and 141.

For example, the drive signal which is output from the drive circuit is transmitted to the second substrate 12 through the connection unit 22. The drive signal which is transmitted to the second substrate 12 is transmitted to each circuit of a pixel including the photoelectric conversion unit 121 through the interconnection 126 and the via 127. In addition, the drive signal which is transmitted to the second substrate 12 is transmitted to the third substrate 14 through the connection unit 21. The drive signal which is transmitted to the third substrate 14 is transmitted to each circuit of a pixel including the photoelectric conversion unit 141 through the interconnection 146 and the via 147.

In this embodiment, the processing circuit or the drive circuit is disposed in the support substrate 31. Accordingly, the processing circuit or the drive circuit may not be provided in a substrate in which the photoelectric conversion unit is formed. Alternatively, a part of a processing circuit or a drive circuit which is disposed in the substrate in which the photoelectric conversion unit is formed may be moved to the support substrate 31. According to this, it is possible to further reduce the size of the solid-state imaging device in comparison to a case where the processing circuit or the drive circuit is provided in the substrate in which the photoelectric conversion unit is formed. In addition, it is possible to add the processing circuit to the support substrate 31. Accordingly, it is possible to implement many functions by the solid-state imaging device.

### Fourth Embodiment

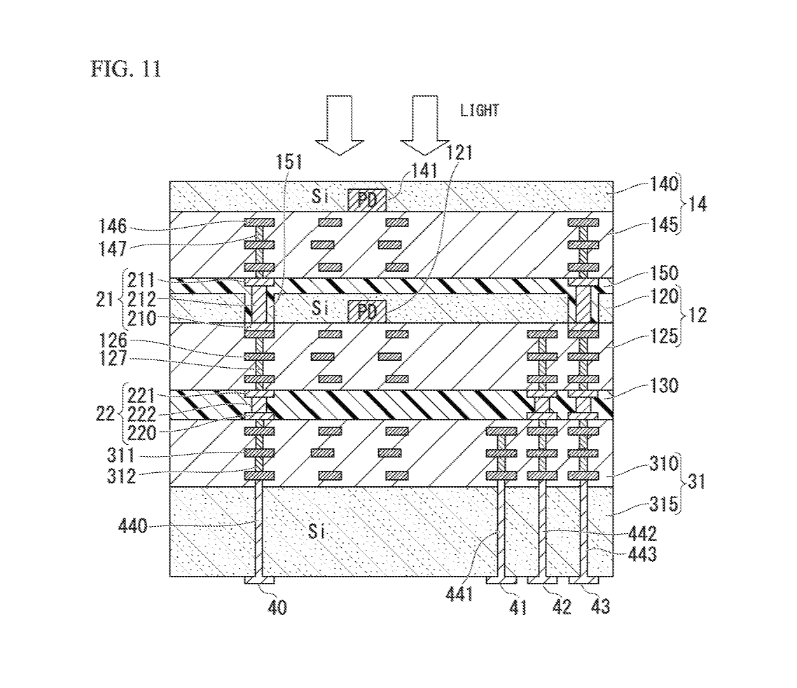

Next, description will be given of a fourth embodiment of the invention. FIG. 11 shows a configuration example of the solid-state imaging device according to this embodiment. In FIG. 11, a cross-section of the solid-state imaging device is shown.

In the solid-state imaging device shown in FIG. 11, the electrode structure in the solid-state imaging device shown in FIG. 10 is changed to a different structure. Structures other than the electrode structure are substantially the same as the structures of the solid-state imaging device shown in FIG. 10, and thus description of the structures other than the electrode structure will not be repeated.

In the circuit substrate 315, electrodes 40, 41, 42, and 43 are formed in the first surface which is opposite to the second surface that comes into contact with the interconnection layer 310. The electrodes 40, 41, 42, and 43 are constituted by a material having conductivity. The electrode 40 and the interconnection 311 are connected to each other by a through-electrode 440 that passes through the circuit substrate 315. The electrode 41 and the interconnection 311 are connected to each other by a through-electrode 441 that passes through the circuit substrate 315. The electrode 42 and the interconnection 311 are connected to each other by a through-electrode 442 that passes through the circuit substrate 315. The electrode 43 and the interconnection 311 are connected to each other by a through-electrode 443 that passes through the circuit substrate 315. The through-electrodes 440, 441, 442, and 443 are constituted by a material having conductivity.

That is, the solid-state imaging device shown in FIG. 11 includes a support substrate 31 that overlaps the second substrate 12 that is disposed on an outermost side among the plurality of substrates in which the photoelectric conversion unit is formed. More specifically, the solid-state imaging device shown in FIG. 11 includes the support substrate 31 that overlaps the second substrate 12, in which the interconnection layer 125 is disposed on an outer side in comparison to the semiconductor layer 120, as a substrate that is disposed on an outermost side among the plurality of substrates in which the photoelectric conversion unit is formed. The support substrate 31 includes the electrodes 40, 41, 42, and 43 which are electrically connected to the interconnection layer 125 of the second substrate 12 overlapping the support substrate 31 among the plurality of substrates in which the photoelectric conversion unit is formed and which are exposed to an outer side.

For example, the electrode 40 is used for a power supply, a ground (GND), or a clock which is common in the respective substrates. For example, the electrodes 41, 42, and 43 are used for individual signals of the respective substrates.

For example, a signal which is output from the photoelectric conversion unit 121 is transmitted to the support substrate 31 through the connection unit 22 at a position at which the electrode 42 is formed. The signal which is transmitted to the support substrate 31 is transmitted to the electrode 42 through the through-electrode 442. The signal which is transmitted to the electrode 42 is output from the electrode 42 to an outer side. For example, a signal which is output from the photoelectric conversion unit 141 is transmitted to the second substrate 12 through the connection unit 21 at a position at which the electrode 43 is formed. The signal which is transmitted to the second substrate 12 is transmitted to the support substrate 31 through the connection unit 22. The signal which is transmitted to the support substrate 31 is transmitted to the electrode 43 through the through-electrode 443. The signal which has transmitted to the electrode 43 is output from the electrode 43 to an outer side.

In a sequence of manufacturing the solid-state imaging device shown in FIG. 11, the support substrate 31 is used instead of the first substrate 10, the resin layer 110, and the support substrate 30 in the sequence of manufacturing the solid-state imaging device shown in FIG. 1, and the connection unit 22 is formed instead of the connection unit 20. For example, after the second substrate 12 and the third substrate 14 are connected to each other, the first surface of the circuit substrate 315 is polished, and the circuit substrate 315 becomes thin. Then, a groove that passes through the circuit substrate 315 is formed. The groove is buried with a metal to form the electrodes 40, 41, 42, and 43, and the through-electrodes 440, 441, 442, and 443. A sequence other than the above-described configuration is substantially the same as the sequence of manufacturing the solid-state imaging device shown in FIG. 1, and thus description of the sequence of manufacturing the solid-state imaging device shown in FIG. 11 will not be repeated.

In this embodiment, the electrodes 40, 41, 42, and 43, and the through-electrodes 440, 441, 442, and 443 are formed in the support substrate 31, but the electrodes 40, 41, 42, and 43, and the through-electrodes 440, 441, 442, and 443 may be formed in the support substrate 30 of the solid-state imaging device shown in FIG. 1 or FIG. 9.

In this embodiment, the electrodes 40, 41, 42, and 43 are formed in the support substrate 31. According to this, in a case of forming a package including the solid-state imaging device, the electrodes 40, 41, 42, and 43, and a substrate on which the package is mounted can be connected to each other through solder and the like. In a case where an electrode is provided on a surface of the third substrate 14, and the electrode is connected to a wire from an outer side through wire bonding to form a package, a lead which is connected to the wire is necessary and an area of the package increases. Accordingly, in this embodiment, it is possible to further reduce an area of the package.

### Fifth Embodiment

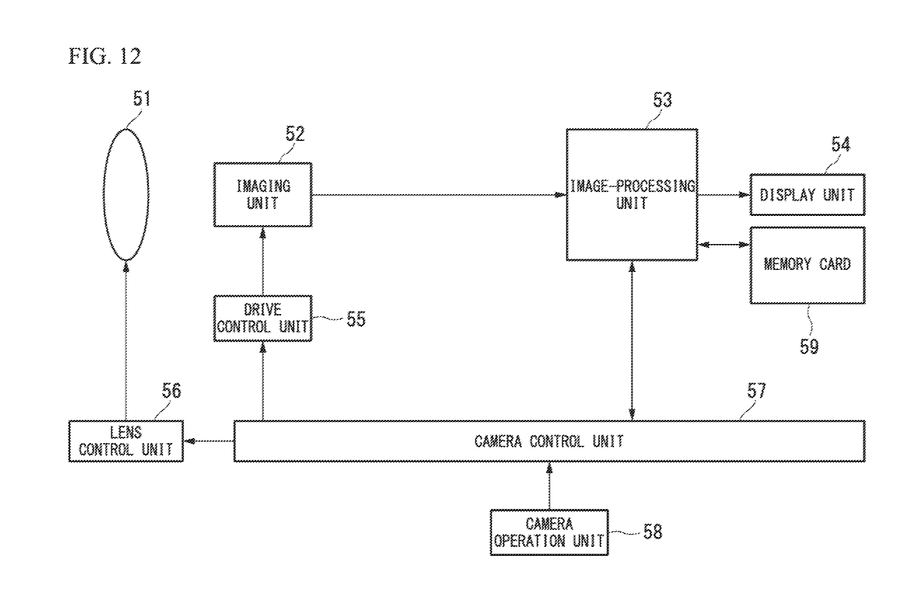

Next, description will be given of a fifth embodiment of the invention. FIG. 12 shows a configuration example of an imaging device according to this embodiment. The imaging device according to this embodiment may be an electronic apparatus having an imaging function, and may be a digital video camera, an endoscope, and the like other than a digital camera.

The imaging device shown in FIG. 12 includes a lens 51, an imaging unit 52, an image-processing unit 53, a display unit 54, a drive control unit 55, a lens control unit 56, a camera control unit 57, and a camera operation unit 58. A memory card 59 is also shown in FIG. 12, and the memory card 59 may be configured to be detachable from the imaging device. That is, the memory card 59 may not be a configuration that is specific to the imaging device.

The lens 51 is an imaging lens that forms an optical image of a subject to an imaging surface of the imaging unit 52 that constitutes the solid-state imaging device. The imaging unit 52 converts the optical image of the subject which is formed by the lens 51 to a digital image signal through photoelectric conversion, and outputs the image signal. The imaging unit 52 is any one of the solid-state imaging devices according to the first embodiment to the fourth embodiment. The image-processing unit 53 performs various kinds of digital image processing with respect to the image signal that is output from the imaging unit 52.

The display unit 54 displays an image on the basis of the image signal that is image-processed for display by the image-processing unit 53. The display unit 54 can display a still image, and can perform moving image (live view) display in which images in an imaging range are displayed in real time. The drive control unit 55 controls an operation of the imaging unit 52 on the basis of an instruction transmitted from the camera control unit 57. The lens control unit 56 controls a focal position of an aperture of the lens 51 on the basis of the instruction transmitted from the camera control unit 57.

The camera control unit 57 controls the entirety of the imaging device. The operation of the camera control unit 57 is defined by a program that is stored in a ROM that is embedded in the imaging device. The camera control unit 57 reads out the program, and performs various kinds of control in accordance with the contents defined by the program.

The camera operation unit 58 includes various kinds of operation members which allow a user to perform various kinds of operation input with respect to the imaging device, and outputs a signal based on an operation input result to the camera control unit 57. Specific examples of the camera operation unit 58 include a power switch that turns on and off a power supply of the imaging device, a release button that gives an instruction of capturing of a still image, a still image-capturing mode switch that switches a still image-capturing mode between a single mode and a consecutive mode, and the like. The memory card 59 is a recording medium that stores the image signal that is processed for recording by the image-processing unit 53.

In this embodiment, any one of the solid-state imaging device according to the first embodiment to the fourth embodiment is used as the imaging unit 52. According to this, it is possible to more easily manufacture the imaging device.

Hereinbefore, the embodiments of the invention have been described in detail with reference to the accompanying drawings. However, specific configurations include design modifications in a range not departing from the gist of the invention without limitation to the above-described embodiments. The invention is not limited to the above description, and is limited by only a range of the attached claims.

While preferred embodiments of the invention have been described and shown above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A solid-state imaging device, comprising:
a plurality of substrates provided to be overlapped; and
a connection structure,
wherein each of the substrates includes a semiconductor layer in which a photoelectric conversion unit configured to convert incident light to a signal is formed, and an interconnection layer in which an interconnection configured to transmit the signal is formed and which overlaps the semiconductor layer,
the semiconductor layer of a first substrate and the interconnection layer of a second substrate in two adjacent substrates among the plurality of substrates are disposed to face each other, and
the connection structure is formed on a surface which faces the semiconductor layer of the first substrate of the interconnection layer of the second substrate to electrically connect the interconnection layer of the first substrate and the interconnection layer of the second substrate, and passes through only the semiconductor layer of the first substrate out of the semiconductor layer of the first substrate and the interconnection layer of the second substrate.

2. The solid-state imaging device according to claim 1, further comprising:
a resin layer that is formed between the semiconductor layer of the first substrate and the interconnection layer of the second substrate.

3. The solid-state imaging device according to claim 2,
wherein the periphery of a portion which passes through the semiconductor layer of the connection structure is covered with a resin.

4. The solid-state imaging device according to claim 1, further comprising:
a support substrate that overlaps a substrate which is disposed on an outermost side among the plurality of substrates,
wherein the support substrate includes a processing circuit that processes the signal that is generated in the photoelectric conversion unit formed in any one of the plurality of substrates.

5. The solid-state imaging device according to claim 1, further comprising:
a support substrate that overlaps a substrate which is disposed on an outermost side among the plurality of substrates,
wherein the support substrate includes a drive circuit that drives a pixel including the photoelectric conversion unit formed in any one of the plurality of substrates.

6. The solid-state imaging device according to claim 1,
wherein a substrate that is disposed on an outermost side among the plurality of substrates, the substrate, in which the semiconductor layer is disposed on an outer side in comparison to the interconnection layer, includes an electrode that is electrically connected to the interconnection layer of the substrate and is exposed to an outer side.

7. The solid-state imaging device according to claim 1, further comprising:
a support substrate that overlaps a substrate which is disposed on an outermost side among the plurality of substrates,
wherein the support substrate includes an electrode that is electrically connected to the interconnection layer of the substrate which overlaps the support substrate among the plurality of substrates and is exposed to an outer side.

8. An imaging device, comprising:
the solid-state imaging device according to claim 1.

9. A method of manufacturing a solid-state imaging device, comprising:
etching a part of a semiconductor layer of a first substrate including the semiconductor layer in which a photoelectric conversion unit configured to convert incident light to a signal is formed, and an interconnection layer in which an interconnection configured to transmit the signal is formed and which overlaps the semiconductor layer, to expose the interconnection layer of the first substrate;
forming a connection structure which is electrically connected to the interconnection layer of a second substrate including the semiconductor layer and the interconnection layer on a surface of the interconnection layer of the second substrate; and
electrically connecting the connection structure which is formed on the surface of the interconnection layer of the second substrate to the interconnection layer of the first substrate which is exposed by the etching of the semiconductor layer of the first substrate in a state in which the semiconductor layer of the first substrate and the interconnection layer of the second substrate face each other.
